(19) United States
(12) Patent Application Publication
(10) Pub. No.: US 2026/0173452 A1
(43) Pub. Date: Jun. 18, 2026

(54) SEMICONDUCTOR DEVICE AND SEMICONDUCTOR MEMORY DEVICE

(71) Applicant: Kioxia Corporation, Tokyo (JP)

(72) Inventor: Kazuki ESHIRO, Yokohama Kanagawa (JP)

(21) Appl. No.: 19/325,759

(22) Filed: Sep. 11, 2025

(30) Foreign Application Priority Data
Dec. 18, 2024 (JP) 2024-221882

(51) Int. Cl. H10D 30/67; H10B 12/00

(52) U.S. Cl. CPC H10D 30/6737; H10B 12/312; H10D 30/6728; H10D 30/6735; H10D 30/6755

(57) ABSTRACT

A semiconductor device includes a channel including an oxide semiconductor; and an electrode in contact with the channel. The electrode includes: a metal layer including at least one of the following metal elements: iridium, palladium, silver, osmium, and rhodium; and a first oxide layer in contact with the metal layer, disposed between the metal layer and the channel, and including the metal element of the metal layer.

### CROSS-REFERENCE TO RELATED APPLICATION

This application is based upon and claims the benefit of priority from Japanese Patent Application No. 2024-221882, filed Dec. 18, 2024, the entire contents of which are incorporated herein by reference.

### FIELD

Embodiments described herein relate generally to a semiconductor device and a semiconductor memory device.

### BACKGROUND

A semiconductor device using an oxide semiconductor as a channel material is known. Examples of the oxide semiconductor include InGaZnO (IGZO), and examples of an electrode material of a source electrode and a drain electrode include tungsten. A process of manufacturing such a semiconductor device involves a heat treatment.

However, in a case where the heat treatment is performed on the semiconductor device, oxygen in a channel material diffuses into the electrode material, and the oxygen deficiency in the channel increases. This causes a failure of the semiconductor device and an increase in the resistance of the channel.

### DESCRIPTION OF THE DRAWINGS

FIG. 1 is a cross-sectional view illustrating a basic configuration of a semiconductor device of an embodiment.

FIG. 2 is a view illustrating an aspect in which oxygen diffusion is reduced in a semiconductor device of the embodiment.

FIG. 3 is a view illustrating an aspect of oxygen diffusion in a semiconductor device according to a comparative example.

FIG. 4 is a view illustrating an aspect of oxygen diffusion in the semiconductor device according to the comparative example.

FIG. 5 is a view illustrating an element amount distribution in a case where iridium is applied as a metal layer.

FIG. 6 is a view illustrating an element amount distribution in a case where iridium is applied as the metal layer.

FIG. 7 is a view illustrating an element amount distribution in a case where titanium nitride is applied as the metal layer.

FIG. 8 is a view illustrating an element amount distribution in a case where ruthenium is applied as the metal layer.

FIG. 9 is a view illustrating an element amount distribution in a case where ruthenium is applied as the metal layer.

FIG. 10 is a view illustrating an example of a gate voltage characteristic in the semiconductor device.

FIG. 11 is a flowchart illustrating a method of generating a first oxide layer in the semiconductor device according to the embodiment.

FIG. 12 is a view illustrating the method of generating the first oxide layer in the semiconductor device according to the embodiment.

FIG. 13 is a view illustrating the method of generating the first oxide layer in the semiconductor device according to the embodiment.

FIG. 14 is a view illustrating the method of generating the first oxide layer in the semiconductor device according to the embodiment.

FIG. 15 is a view illustrating the method of generating the first oxide layer in the semiconductor device according to the embodiment.

FIG. 16 is a flowchart illustrating another method of generating the first oxide layer in the semiconductor device according to the embodiment.

FIG. 17 is a view illustrating the other method of generating the first oxide layer in the semiconductor device according to the embodiment.

FIG. 18 is a view illustrating the other method of generating the first oxide layer in the semiconductor device according to the embodiment.

FIG. 19 is a view illustrating the other method of generating the first oxide layer in the semiconductor device according to the embodiment.

FIG. 20 is a view illustrating the other method of generating the first oxide layer in the semiconductor device according to the embodiment.

FIG. 21 is a circuit diagram illustrating a circuit configuration example of a memory cell array as a semiconductor memory device according to the embodiment.

FIG. 22 is a schematic cross-sectional view illustrating a structural example of the memory cell array as the semiconductor memory device according to the embodiment.

FIG. 23 is a block diagram illustrating a configuration example of the semiconductor memory device according the embodiment.

### DETAILED DESCRIPTION

As described above, a semiconductor device and a semiconductor memory device in the related art have a problem that oxygen in a channel material may diffuse into an electrode material. Embodiments provide a semiconductor device and a semiconductor memory device that can reduce oxygen deficiency in a channel material.

In general, according to one embodiment, a semiconductor device includes a channel including an oxide semiconductor; and an electrode in contact with the channel. The electrode includes: a metal layer including at least one of the following metal elements: iridium, palladium, silver, osmium, and rhodium; and a first oxide layer in contact with the metal layer, disposed between the metal layer and the channel, and including the metal element of the metal layer.

### Configuration of Semiconductor Device of Embodiment

Hereinafter, the semiconductor device according to an embodiment will be described with reference to the drawings. In the embodiments, the same reference numerals may be given to substantially the same components, and description thereof may be partially omitted. The drawings are schematic, and a relationship between a thickness and planar dimensions, a ratio of the thickness of each portion, and the like may be different from actual values.

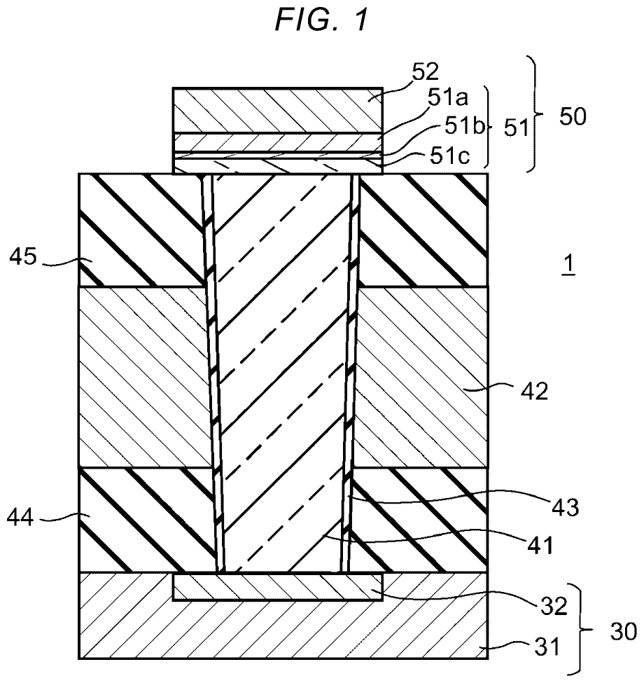

FIG. 1 is a cross-sectional view showing a basic configuration of the semiconductor device according to the embodiment. The semiconductor device 1 shown in FIG. 1 includes a conductor 50 as a source electrode or a drain electrode, a conductor 30 as a drain electrode or a source electrode, insulating layers 44 and 45 disposed between the conductor 50 and the conductor 30, an oxide semiconductor layer 41 as a channel of which both ends are bonded to the conductor 50 and the conductor 30, a conductive layer 42 as a gate electrode that is sandwiched between the insulating layers 44 and 45 between the conductor 50 and the conductor 30 and is disposed in the vicinity of the oxide semiconductor layer 41, and an insulating film 43 disposed at an interface between the oxide semiconductor layer 41, and the insulating layers 44 and 45 and the conductive layer 42.

That is, the conductor 30, the insulating layer 44, the conductive layer 42, and the insulating layer 45 form a stacked body. In this stacked body, the oxide semiconductor layer 41 is disposed to pass through the insulating layer 45, the conductive layer 42, and the insulating layer 44. One end portion of the oxide semiconductor layer 41 is bonded to one main surface of the conductor 30. The insulating film 43 is disposed on a peripheral surface of the oxide semiconductor layer 41 to insulate the oxide semiconductor layer 41 from the conductive layer 42 on an outer periphery. The conductor 50 is disposed on a surface of the insulating layer 45 on a side opposite to a bonding surface with the conductive layer 42. The other end portion of the oxide semiconductor layer 41 is bonded to the conductor 50.

The conductor 50, the conductor 30, and the conductive layer 42 function as electrodes corresponding to a source, a drain, and a gate of a transistor element formed by the semiconductor device 1. This transistor element may configure, for example, a switching transistor in a memory element.

The conductor 30 includes a conductive layer 31 and a conductive oxide layer 32. The conductive layer 31 contains, for example, copper. The conductive oxide layer 32 is directly bonded to one end portion of the oxide semiconductor layer 41 in a bonding surface between the conductor 30 and the insulating layer 44. The conductive oxide layer 32 contains a conductive oxide.

The oxide semiconductor layer 41 contains, for example, indium (In). The oxide semiconductor layer 41 contains, for example, an indium oxide and a gallium oxide, an indium oxide and a zinc oxide, or an indium oxide and a tin oxide. As an example, the oxide semiconductor layer 41 contains an oxide containing indium, gallium, and zinc (indium-gallium-zinc-oxide), so-called InGaZnO (IGZO).

The conductive layer 42 contains, for example, a metal, a metal compound, or a semiconductor. The conductive layer 42 contains, for example, at least one material selected from the group consisting of tungsten (W), titanium (Ti), titanium nitride (TiN), molybdenum (Mo), cobalt (Co), and ruthenium (Ru).

The insulating film 43 contains, for example, silicon, and oxygen or nitrogen. The insulating film 43 may be a stacked film of a plurality of insulating films. The insulating layers 44 and 45 contain, for example, silicon, and oxygen or nitrogen. The insulating layers 44 and 45 are configured with, for example, silicon dioxide (SiO₂).

The conductor 50 includes an intermediate layer 51 and a conductive layer 52. The conductive layer 52 contains, for example, copper or tungsten (W). The intermediate layer 51 is directly bonded to the other end portion of the oxide semiconductor layer 41 in a bonding surface between the conductor 50 and the insulating layer 45. The intermediate layer 51 includes a metal layer 51a, a first oxide layer 51b, and a second oxide layer 51c.

The second oxide layer 51c is a layer that can be bonded to the oxide semiconductor layer 41 in the conductor 50. The second oxide layer 51c contains, for example, indium tin oxide (ITO). The metal layer 51a contains, for example, at least one of iridium (Ir), palladium (Pd), silver (Ag), osmium (Os), and rhodium (Rh). The metal layer 51a is disposed between the second oxide layer 51c and the conductive layer 52.

The first oxide layer 51b is disposed between the second oxide layer 51c and the metal layer 51a. The first oxide layer 51b contains an oxide of a metal element forming the metal layer 51a. That is, the first oxide layer 51b contains, for example, an iridium oxide (IrOx), a palladium oxide (PdOx), a silver oxide (AgOx), an osmium oxide (OsOx), and a rhodium oxide (RhOx). The metal layer 51a and the first oxide layer 51b function as a barrier layer that prevents oxygen (O) contained in the oxide semiconductor layer 41 from diffusing into the conductive layer 52.

Although the semiconductor device 1 shown in FIG. 1 includes the metal layer 51a, the first oxide layer 51b, and the second oxide layer 51c as the intermediate layer 51, the present disclosure is not limited thereto. The intermediate layer 51 may not include the second oxide layer 51c and may be configured with the metal layer 51a and the first oxide layer 51b. In addition, the structure of the conductor 30 including the conductive layer 31 and the conductive oxide layer 32 may have the same structure as the structure of the conductor 50 described above.

### Operation of Semiconductor Device of Embodiment

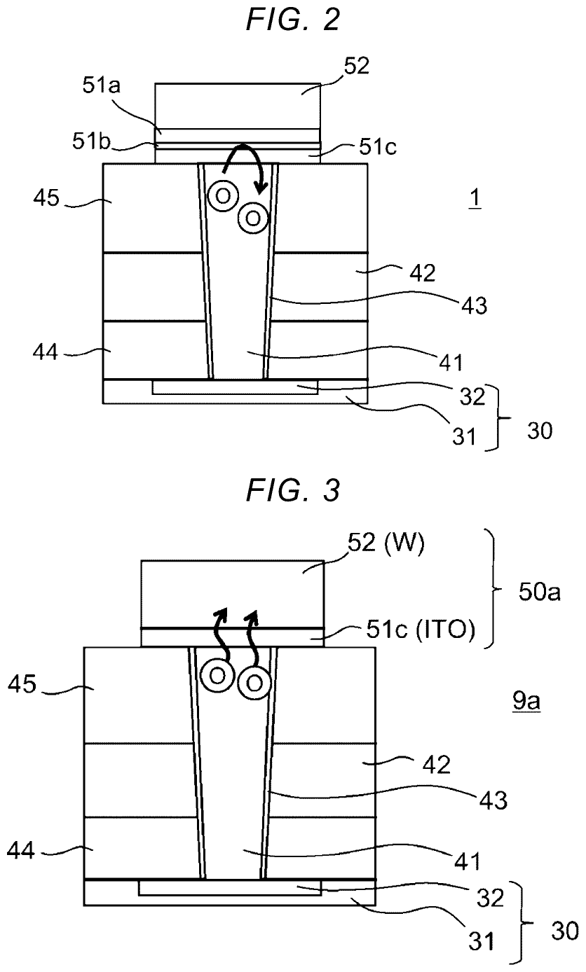

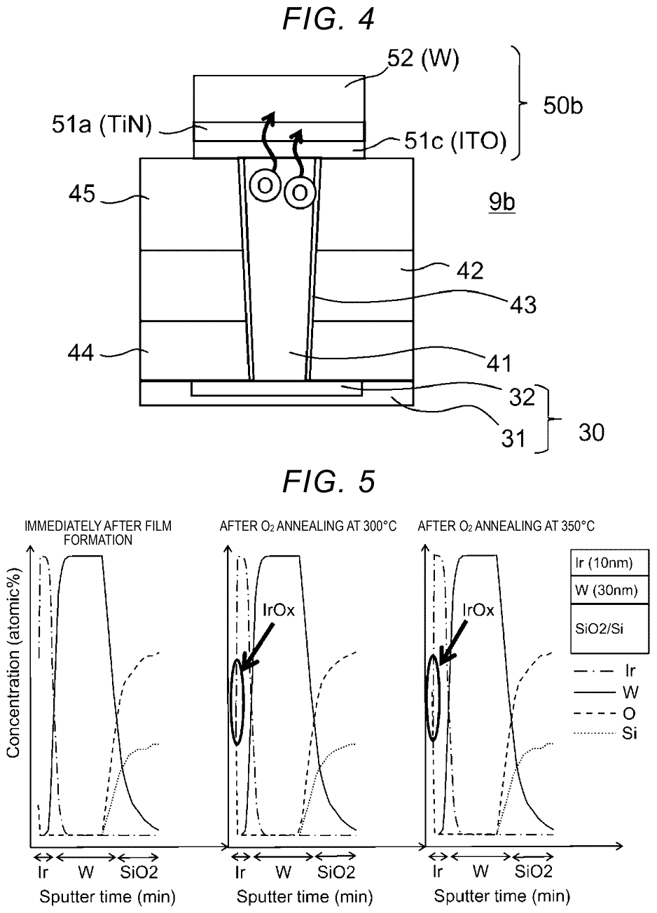

The operation of the embodiment will be described with reference to FIG. 2 to FIG. 4. FIG. 2 is a view showing an aspect in which oxygen diffusion is reduced in the semiconductor device 1 according to the embodiment. FIG. 3 and FIG. 4 are views showing aspects of oxygen diffusion in semiconductor devices of comparative examples.

In a transistor using an oxide semiconductor as a channel, a metal of a bit line material scavenges oxygen in the channel by a heat process in a manufacturing process, and a threshold voltage Vth is significantly decreased. For example, as shown in FIG. 3, in a case where a conductor 50a is not provided with the metal layer 51a and the first oxide layer 51b in a semiconductor device 9a, ITO is applied as the second oxide layer 51c, and tungsten is applied as the conductive layer 52, oxygen in the oxide semiconductor layer 41 as the channel diffuses to tungsten through ITO.

In addition, as shown in FIG. 4, even in a case where a conductor 50b is provided with the metal layer 51a in a semiconductor device 9b, in a case where titanium nitride (TiN) is applied as the metal layer 51a and ITO is applied as the second oxide layer 51c, oxygen in the oxide semiconductor layer 41 as the channel diffuses to tungsten through ITO or titanium nitride. Such oxygen diffusion to the conductive layer 52 increases oxygen deficiency in the channel and becomes a factor that decreases the threshold voltage Vth.

Therefore, as shown in FIG. 2, the semiconductor device 1 of the embodiment includes the metal layer 51a and a conductive oxygen barrier layer (the first oxide layer 51b) between the conductive layer 52 forming the source electrode or the drain electrode and the second oxide layer 51c. For example, in a case where iridium (Ir) is applied as the metal layer 51a, ITO is applied as the second oxide layer 51c, and tungsten (W) is applied as the conductive layer 52, a layer of iridium oxide (IrOx) as the first oxide layer 51b is formed at an interface between ITO and iridium. The iridium oxide has an operation of reducing oxygen diffusion from the channel to the tungsten in combination with the iridium layer.

The same applies even in a case where the semiconductor device 1 does not include the second oxide layer 51c. In a case where iridium is applied as the metal layer 51a and tungsten is applied as the conductive layer 52, a layer of iridium oxide as the first oxide layer 51b is formed at an interface between the channel and the iridium. The iridium oxide has an operation of reducing oxygen diffusion from the channel to the tungsten in combination with the iridium layer.

As described above, the semiconductor device 1 according to the embodiment can prevent the oxygen deficiency in the channel material and reduce a decrease in threshold voltage Vth by appropriately selecting the metal element of the metal layer 51a and including the metal layer 51a and the first oxide layer 51b containing the metal element.

### Formation of First Oxide Layer and Selection of Metal Element of Metal Layer

The first oxide layer 51b in the semiconductor device 1 according to the embodiment may be formed by a heat treatment process related to the manufacturing of the semiconductor device 1. That is, the metal layer 51a containing an appropriate metal element is formed, and a metal oxide containing a metal element forming the metal layer 51a is generated by performing a heat treatment. Therefore, in the semiconductor device 1 according to the embodiment, it is necessary to select a metal element of the metal layer 51a having large oxide generation energy that can generate a metal oxide by the heat treatment process. On the other hand, when the energy for generating an oxide of the metal is too large, the metal is excessively oxidized, and scavenging of oxygen and permeation of oxygen progress. This is a factor that causes an increase in oxygen deficiency in the channel.

Energy for generating oxides of platinum (Pt), silver (Ag), palladium (Pd), iridium (Ir), osmium (Os), and rhodium (Rh) is smaller than energy for generating an oxide of ruthenium (Ru). Among these, platinum (Pt) is not suitable for forming an oxidized layer because the oxide generation energy is too small. On the other hand, in copper (Cu), rhenium (Re), nickel (Ni), cobalt (Co), iron (Fe), and the like, which have higher oxide generation energy as compared with ruthenium (Ru), formation of an oxidized layer proceeds too far. Therefore, in the semiconductor device 1 according to the embodiment, it is preferable to select silver (Ag), palladium (Pd), iridium (Ir), osmium (Os), or rhodium (Rh) as the metal layer 51a.

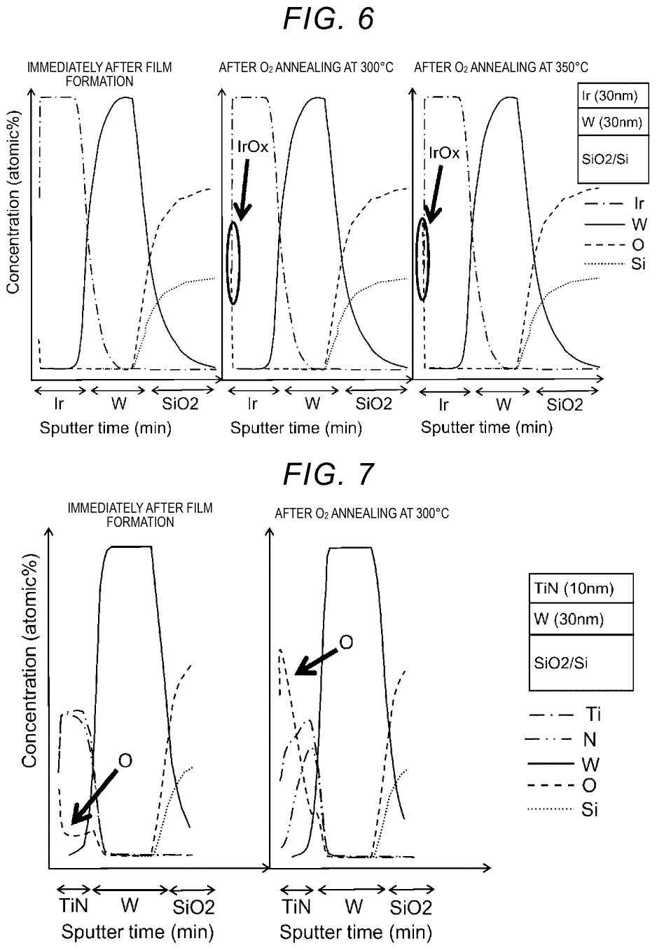

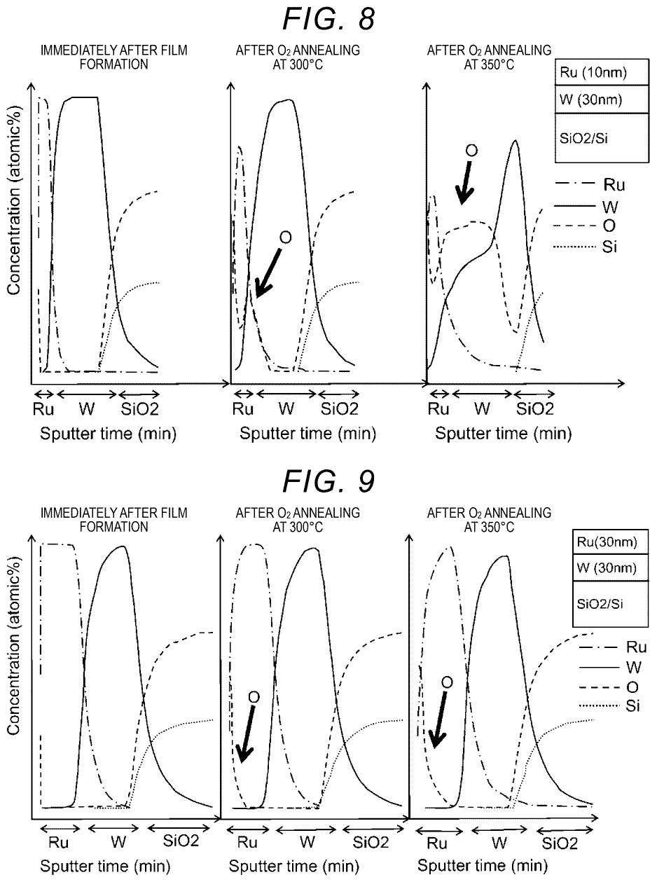

Referring to FIG. 5 to FIG. 9, an aspect of oxide film formation and oxygen diffusion in a case where a conductive layer and a metal layer are formed on a SiO₂ substrate and an oxygen annealing is performed will be described. FIG. 5 to FIG. 6 are views showing an element amount distribution in a case where iridium is applied as the metal layer. FIG. 7 is a view showing an element amount distribution in a case where titanium nitride is applied as the metal layer. FIG. 8 to FIG. 9 are views showing an element amount distribution in a case where ruthenium is applied as the metal layer. FIG. 5 to FIG. 9 show results of analysis of an element composition ratio in a depth direction from a sample surface to the SiO₂ substrate by using X-ray photoelectron spectroscopy (XPS) in combination with ion etching. That is, FIG. 5 to FIG. 9 show element amount distributions in the depth direction of the sample.

FIG. 5 shows an aspect of forming an oxide film in a case where oxygen annealing is performed on a sample in which a tungsten layer having a thickness of 30 nm is formed as the conductive layer 52 on the substrate (SiO₂), and an iridium layer having a thickness of 10 nm is further formed as the metal layer 51a on a surface of the tungsten layer. FIG. 5 shows an element concentration at each position from a sample surface toward the substrate from left to right under three conditions of immediately after film formation, after oxygen annealing at 300° C., and after oxygen annealing at 350° C. with respect to a prepared sample.

As shown in FIG. 5, immediately after film formation, an oxygen concentration on the sample surface is low, while an iridium concentration is high. After the oxygen annealing at 300° C., a region in which a high oxygen concentration and a low iridium concentration overlap each other can be observed in the vicinity of the sample surface. This indicates that the iridium oxide is generated as the first oxide layer 51b in the overlapping portion of both. The same applies in a case where the oxygen annealing at 350° C. is performed, and the generation of iridium oxide can be observed in the vicinity of the sample surface. The oxygen observed on the sample surface is oxygen derived from the iridium oxide. That is, the iridium oxide remains on a surface of the iridium layer, and the oxygen concentration in the iridium layer and the tungsten layer is significantly low. From this, it is understood that oxygen is used to generate the iridium oxide, but does not diffuse to the tungsten layer.

FIG. 6 shows an aspect of forming an oxide film in a case where oxygen annealing is performed on a sample in which a tungsten layer having a thickness of 30 nm is formed as the conductive layer 52 on a substrate (SiO₂), and an iridium layer having a thickness of 30 nm is further formed on the surface of the tungsten layer as the metal layer 51a. FIG. 6 shows the element concentration at each position from the sample surface toward the substrate from left to right under three conditions of immediately after film formation, after oxygen annealing at 300° C., and after oxygen annealing at 350° C. with respect to a prepared sample.

As shown in FIG. 6, immediately after film formation, the oxygen concentration on the sample surface is low, while the iridium concentration is high. After the oxygen annealing at 300° C., a region in which a high oxygen concentration and a low iridium concentration overlap each other can be observed in the vicinity of the sample surface. This indicates that the iridium oxide is generated as the first oxide layer 51b in the overlapping portion of both. The same applies in a case where the oxygen annealing at 350° C. is performed, and the generation of iridium oxide can be observed in the vicinity of the sample surface. The oxygen observed on the sample surface is oxygen derived from the iridium oxide. That is, the iridium oxide remains on a surface of the iridium layer, and the oxygen concentration in the iridium layer and the tungsten layer is significantly low. As shown in FIG. 5 and FIG. 6, it is understood that oxygen diffusion into the tungsten layer is reduced regardless of the thickness in a case where iridium is applied as the metal layer 51a.

FIG. 7 shows an aspect of forming an oxide film in a case where oxygen annealing is performed on a sample in which a tungsten layer having a thickness of 30 nm is formed as the conductive layer 52 on a substrate (SiO₂), and a titanium nitride layer having a thickness of 10 nm is further formed as the metal layer 51a on the surface of the tungsten layer. FIG. 7 shows the element concentration at each position from the sample surface toward the substrate from left to right under two conditions immediately after film formation and after oxygen annealing at 300° C. with respect to a prepared sample.

As shown in FIG. 7, immediately after film formation, a certain oxygen concentration is observed not only on the sample surface but also inside the titanium nitride layer. After the oxygen annealing at 300° C., a high oxygen concentration is observed in the vicinity of the sample surface, while a titanium concentration and a nitrogen concentration are observed at the same concentration as in immediately after film formation. This means that an oxide film of titanium nitride is not generated and oxygen diffuses through the titanium nitride layer. From this, it can be seen that oxygen is not used to generate the titanium nitride oxide, and oxygen diffuses into the titanium nitride layer.

FIG. 8 shows an aspect of forming an oxide film in a case where oxygen annealing is performed on a sample in which a tungsten layer having a thickness of 30 nm is formed as the conductive layer 52 on a substrate (SiO₂), and a ruthenium layer having a thickness of 10 nm is further formed on the surface of the tungsten layer as the metal layer 51a. FIG. 8 shows the element concentration at each position from the sample surface toward the substrate from left to right under three conditions of immediately after film formation, after oxygen annealing at 300° C., and after oxygen annealing at 350° C. with respect to a prepared sample.

As shown in FIG. 8, immediately after film formation, an oxygen concentration on the sample surface is low, while a ruthenium concentration is high. After the oxygen annealing at 300° C., the ruthenium concentration on the sample surface is still high, and the oxygen concentration at an interface between a ruthenium layer and a tungsten layer is observed to be high. After the oxygen annealing at 350° C., it is observed that oxygen diffuses into a region that is the tungsten layer. That is, it is understood that the oxygen concentration increases at an interface between ruthenium and tungsten, and oxygen greatly diffuses into the tungsten layer after the oxygen annealing at 350° C.

FIG. 9 shows an aspect of forming an oxide film in a case where oxygen annealing is performed on a sample in which a tungsten layer having a thickness of 30 nm is formed as the conductive layer 52 on a substrate (SiO₂), and a ruthenium layer having a thickness of 30 nm is further formed as the metal layer 51a on the surface of the tungsten layer. FIG. 9 shows the element concentration at each position from the sample surface toward the substrate from left to right under three conditions of immediately after film formation, after oxygen annealing at 300° C., and after oxygen annealing at 350° C. with respect to a prepared sample.

As shown in FIG. 9, immediately after film formation, an oxygen concentration on the sample surface is low, while a ruthenium concentration is high. After the oxygen annealing at 300° C., an aspect in which the oxygen concentration in the ruthenium layer increases is observed, but the increase in the oxygen concentration is further reduced as compared with a case of the ruthenium layer having a thickness of 10 nm shown in FIG. 8. After the oxygen annealing at 350° C., the oxygen concentration in the ruthenium layer is higher than that after the oxygen annealing at 300° C., but the oxygen diffusion into the tungsten layer is not observed. Therefore, oxygen is not used for the generation of a tungsten oxide. When the thickness of the ruthenium layer is increased, the oxygen diffusion is reduced, but it is understood that oxygen diffuses in the ruthenium layer. In addition, in a case where ruthenium is used as a metal element of the metal layer, it is understood that the oxygen diffusion depends on a film thickness.

As described above, it is understood that the metal element applied as the metal layer 51a affects the generation of the first oxide layer 51b, and the oxygen diffusion from the channel to the metal layer 51a or the conductive layer 52 is not prevented. As the metal element to be selected, iridium (Ir) is preferable, and at least one of palladium (Pd), silver (Ag), osmium (Os), and rhodium (Rh) is preferable.

### Change in Characteristics of Metal Layer Due to Metal Element and Heat Treatment

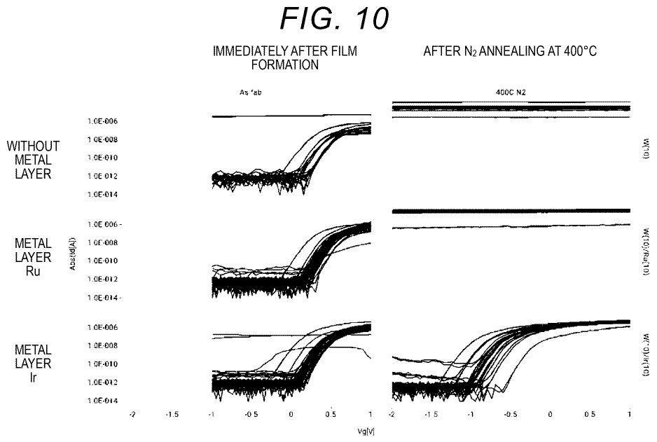

Referring to FIG. 10, a relationship between the metal element of the metal layer 51a and the heat resistance will be described. FIG. 10 shows gate voltage characteristics in a case where the metal layer 51a is not provided, in a case where ruthenium is applied as the metal element of the metal layer 51a, and in a case where iridium is applied as the metal element of the metal layer 51a in the semiconductor device shown in FIG. 1.

As shown in FIG. 10, all of the semiconductor devices function as a semiconductor device immediately after the film formation, but it is shown that the semiconductor devices do not function as a semiconductor device after nitrogen annealing at 400° C. in a case where the metal layer 51 a is not provided and in a case where ruthenium is applied as the metal element of the metal layer 51a. On the other hand, in a case where iridium is applied as the metal element of the metal layer 51a, a cut-off operation is performed even after nitrogen annealing at 400° C. That is, it is understood that iridium is also excellent in heat resistance in a case of being applied as the metal element of the metal layer 51a.

### Creation Method 1 of Embodiment

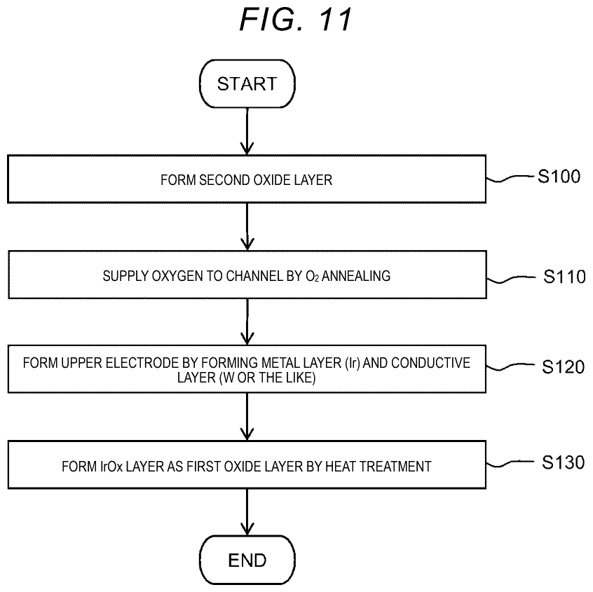

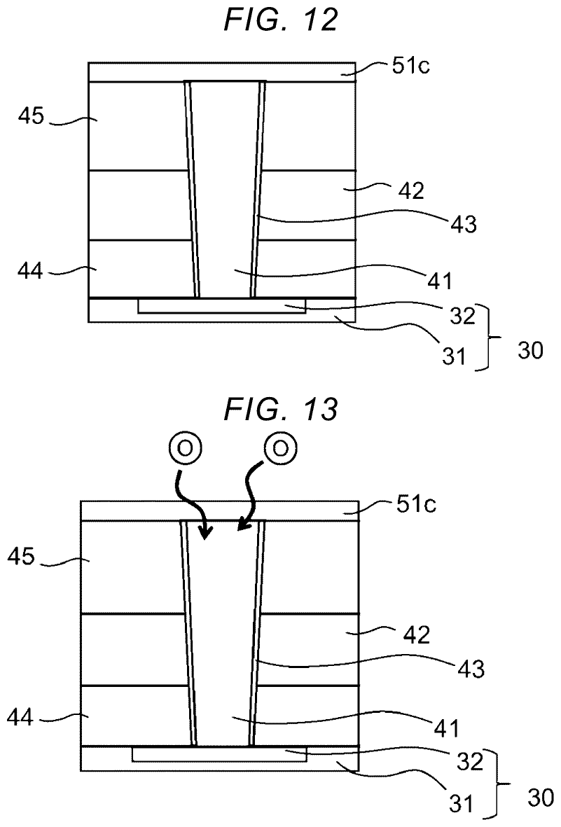

Next, a method of generating the metal layer 51a and the first oxide layer 51b in the semiconductor device 1 according to the embodiment will be described with reference to FIG. 11 to FIG. 15. FIG. 11 is a flowchart showing a method of generating the metal layer 51a and the first oxide layer 51b in the semiconductor device of the embodiment. FIG. 12 to FIG. 15 are conceptual views showing cross sections according to the method of generating the metal layer 51a and the first oxide layer 51b.

As shown in FIG. 12, the conductor 30, the insulating layer 44, the conductive layer 42, and the insulating layer 45 are stacked, and then a hole is opened to pass through the insulating layer 44, the conductive layer 42, and the insulating layer 45, and the insulating film 43 and the oxide semiconductor layer 41 are formed in the hole. Next, the second oxide layer 51c is bonded to an end surface of the oxide semiconductor layer 41 on the surface of the insulating layer 45 (S100). As the second oxide layer 51c, for example, ITO may be applied.

Next, as shown in FIG. 13, oxygen annealing is performed to supply oxygen to the oxide semiconductor layer 41 (S110). For example, IGZO may be applied as the oxide semiconductor layer 41.

Subsequently, as shown in FIG. 14, the metal layer 51a and the conductive layer 52 are formed on a surface of the second oxide layer 51c to form an upper electrode (S120). Here, iridium is applied as the metal layer 51a, and tungsten is applied as the conductive layer 52.

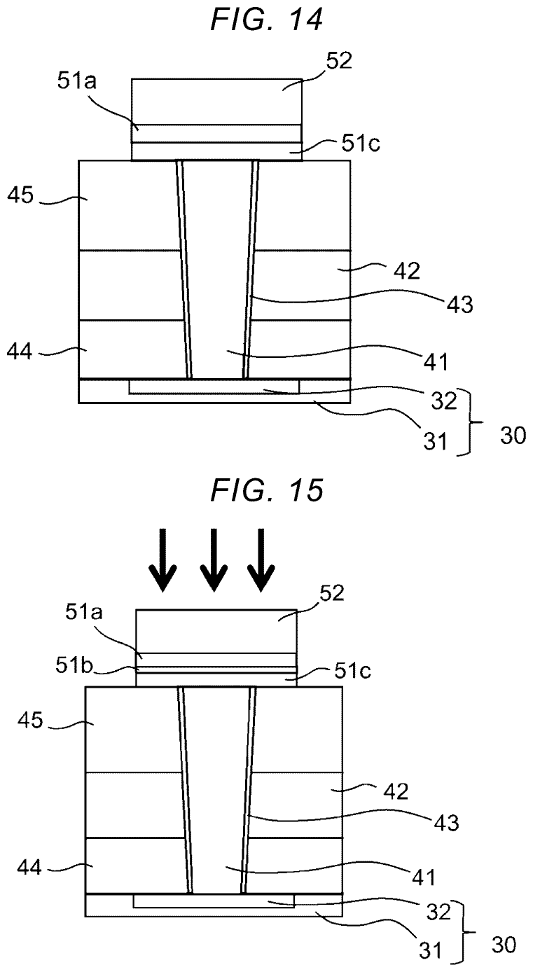

As shown in FIG. 15, a heat treatment is performed to form a layer of an iridium oxide as the first oxide layer 51b at an interface between the second oxide layer 51c and the metal layer 51a (S130).

### Creation Method 2 of Embodiment

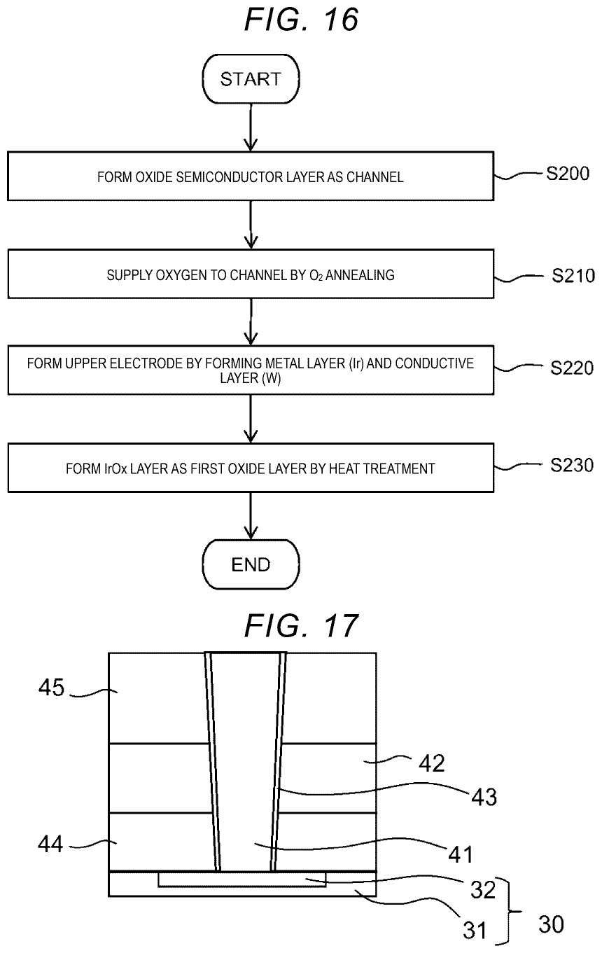

Next, another example of the method of generating the metal layer 51a and the first oxide layer 51b in the semiconductor device 1 according to the embodiment will be described with reference to FIG. 16 to FIG. 20. FIG. 16 is a flowchart showing another method of generating the metal layer 51a and the first oxide layer 51b in the semiconductor device of the embodiment. FIG. 17 to FIG. 20 are conceptual views showing cross sections according to the other method of generating the metal layer 51a and the first oxide layer 51b.

As shown in FIG. 17, the conductor 30, the insulating layer 44, the conductive layer 42, and the insulating layer 45 are stacked, and then a hole is opened to pass through the insulating layer 44, the conductive layer 42, and the insulating layer 45, and the insulating film 43 and the oxide semiconductor layer 41 are formed in the hole (S200).

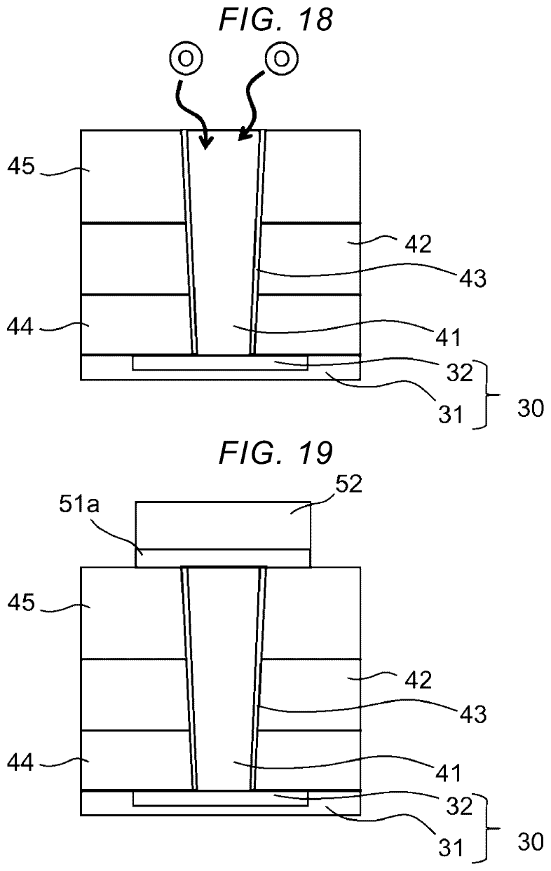

Next, as shown in FIG. 18, oxygen annealing is performed to supply oxygen to the oxide semiconductor layer 41 (S210). For example, IGZO may be applied as the oxide semiconductor layer 41.

Subsequently, as shown in FIG. 19, the metal layer 51a is formed on the surface of the insulating layer 45 to be bonded to the end surface of the oxide semiconductor layer 41, and the conductive layer 52 is further formed on a surface of the metal layer 51a to form an upper electrode (S220). Here, iridium is applied as the metal layer 51a, and tungsten is applied as the conductive layer 52.

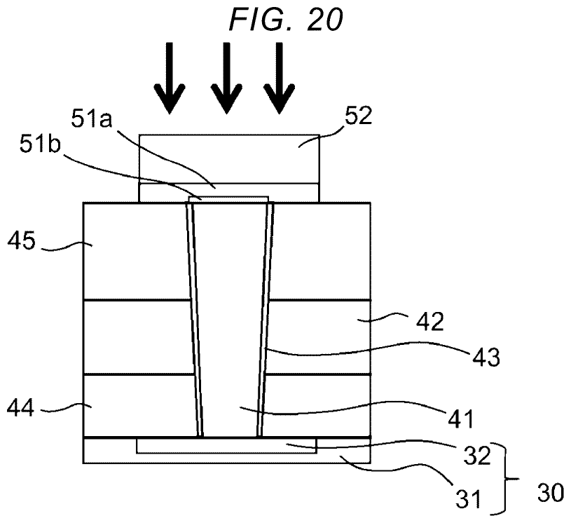

As shown in FIG. 20, the heat treatment is performed to form a layer of an iridium oxide as the first oxide layer 51b at an interface between the oxide semiconductor layer 41 and the metal layer 51a (S230).

According to the method of generating the first oxide layer 51b, a metal layer-derived oxide film can be generated by the heat treatment process in the process of manufacturing the semiconductor device.

### Semiconductor Device as Memory Device

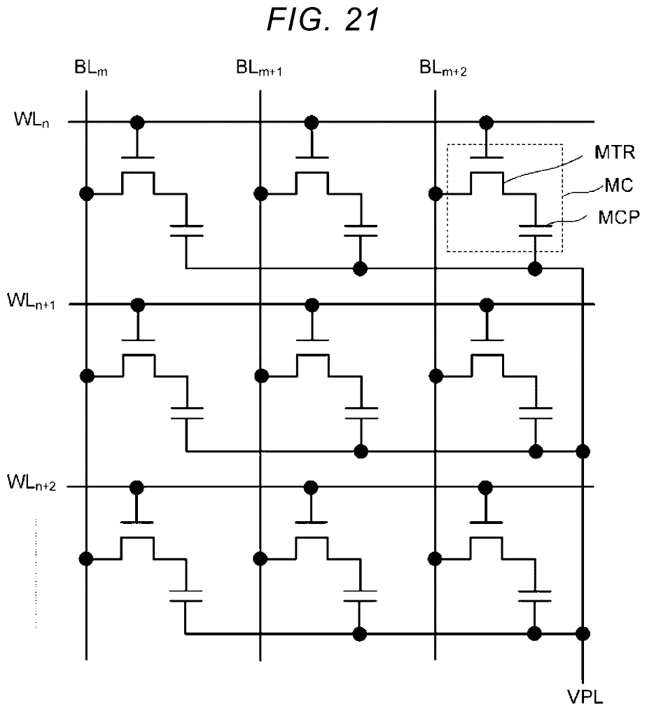

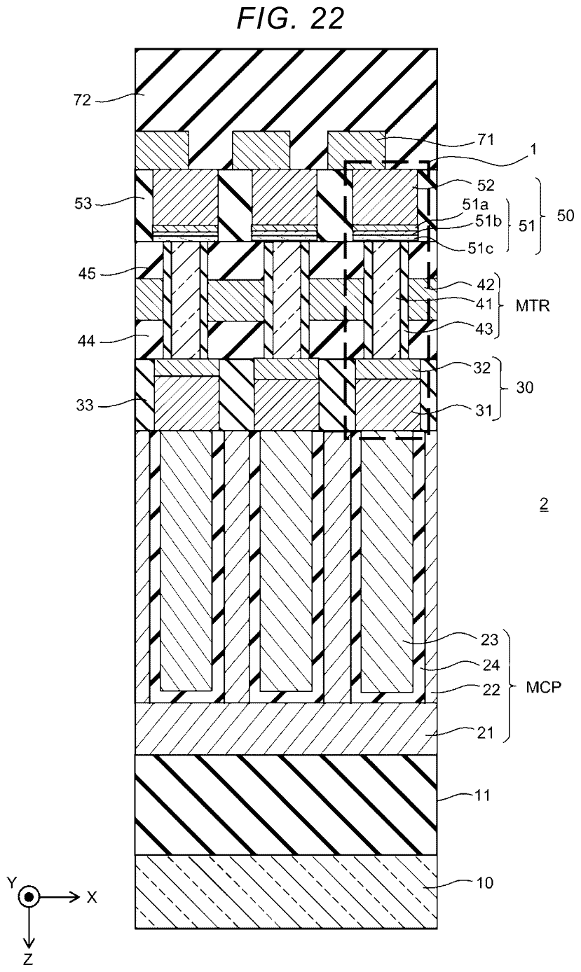

Next, a semiconductor memory device including the semiconductor device 1 according to the embodiment will be described with reference to FIG. 1, FIG. 21, and FIG. 22. FIG. 21 is a circuit diagram for explaining a circuit configuration example of a memory cell array 2 as the semiconductor memory device according to the embodiment. FIG. 21 shows a plurality of memory cells MC, a plurality of word lines WL (a word line WLn, a word line WLn+1, and a word line WLn+2, n being an integer), a plurality of bit lines BL (a bit line BLm, a bit line BLm+1, and a bit line BLm+2, m being an integer), and a power supply line VPL.

The plurality of memory cells MC are arranged in a matrix direction to form the memory cell array 2. Each of memory cells MC includes a memory transistor MTR which is a field effect transistor (FET) and a memory capacitor MCP. The memory transistor MTR corresponds to the semiconductor device 1 according to the embodiment. A gate (conductive layer 42) of the memory transistor MTR is connected to the corresponding word line WL, and one of the source (conductor 50) or the drain (conductor 30) is connected to the corresponding bit line BL. The word line WL is connected to, for example, a row decoder. The bit line BL is connected to, for example, a sense amplifier. A first electrode of the memory capacitor MCP is connected to the other of the source or the drain of the memory transistor MTR, and the second electrode is connected to the power supply line VPL that supplies a specific potential. The power supply line VPL is connected to, for example, a power supply circuit. The memory cell MC can accumulate charges from the bit line BL in the memory capacitor MCP by switching of the memory transistor MTR by the word line WL and can store data. In addition, the memory cell MC can read the data based on the charges accumulated in the memory capacitor MCP to the bit line BL by switching the memory transistor MTR by the word line WL. The number of the plurality of memory cells MC is not limited to the number shown in FIG. 21.

FIG. 22 is a schematic cross-sectional view showing a structural example of the memory cell array 2. FIG. 22 shows a part of a X-Z cross section among an X-axis, a Y-axis, and a Z-axis orthogonal to each other. As shown in FIG. 22, the memory cell array 2 includes a conductor 21, a conductive layer 22, an electrical conductor 23, an insulator 24, the conductive layer 31, the conductive oxide layer 32, the oxide semiconductor layer 41, the conductive layer 42, the insulating film 43, the intermediate layer 51, the conductive layer 52, and a conductive layer 71.

The memory transistor MTR and the memory capacitor MCP are provided above an insulating layer 11 on a semiconductor substrate 10 as shown in FIG. 22. The transistor of the above-described embodiment can be used for the memory transistor MTR. Peripheral circuits such as a row decoder, a sense amplifier, or a power supply circuit are formed on the semiconductor substrate 10. The peripheral circuit includes, for example, a field effect transistor such as a P-channel type field effect transistor (Pch-FET) or an N-channel type field effect transistor (Nch-FET). The field effect transistor can be formed using the semiconductor substrate 10 such as a single crystal silicon substrate, and the Pch-FET and the Nch-FET include a channel region, a source region, and a drain region in the semiconductor substrate 10. The semiconductor substrate 10 may have a P-type conductivity type. The insulating layer 11 is provided on the semiconductor substrate 10 and contains, for example, silicon (Si) and oxygen (O) or nitrogen (N). The insulating layer 11 may be a stacked film.

The conductor 21, the conductive layer 22, the electrical conductor 23, and the insulator 24 form the memory capacitor MCP. The memory capacitor MCP is a three-dimensional capacitor such as a so-called pillar-type capacitor or a cylinder-type capacitor.

The conductor 21 is provided above the semiconductor substrate 10 with the insulating layer 11 sandwiched therebetween. The conductive layer 22 is provided on a part of the conductor 21. The conductor 21 and the conductive layer 22 form a second electrode of the memory capacitor MCP. The conductor 21 extends to overlap the plurality of electrical conductors 23 when viewed in the Z-axis direction. The conductor 21 is also referred to as a plate electrode. The electrical conductor 23 is provided above the conductor 21 with the insulator 24 sandwiched therebetween, extends in the Z-axis direction, and forms a first electrode of the memory capacitor MCP. The insulator 24 is provided between the conductor 21 and the conductive layer 22 and the electrical conductor 23 to form a dielectric of the memory capacitor MCP.

The conductor 21 and the conductive layer 22 contain, for example, a material such as tungsten or titanium nitride. The electrical conductor 23 contains, for example, a material such as tungsten, titanium nitride, or amorphous silicon. The insulator 24 contains, for example, a material such as hafnium oxide, zirconium oxide, or aluminum oxide.

The conductive layer 31 is provided on the electrical conductor 23 and is electrically connected to the electrical conductor 23. The conductive layer 31 contains, for example, copper. The conductive layer 31 does not necessarily have to be formed.

The conductive oxide layer 32 is provided on the conductive layer 31. The conductive oxide layer 32 contains a conductive oxide of the embodiment.

The conductive layer 31 and the conductive oxide layer 32 form the conductor 30. A plurality of the conductors 30 are provided with respect to the plurality of the electrical conductors 23. An insulating layer 33 is formed between the plurality of conductors 30. The insulating layer 33 contains, for example, silicon and oxygen or nitrogen.

The oxide semiconductor layer 41, the conductive layer 42, and the insulating film 43 form the memory transistor MTR. The memory transistor MTR is, for example, an N-channel field effect transistor. The memory transistor MTR is provided above the memory capacitor MCP. A plurality of memory transistors MTR correspond to the plurality of memory capacitors MCP. The insulating layer 44 and the insulating layer 45 are formed between the plurality of memory transistors MTR. The insulating layer 44 and the insulating layer 45 contain, for example, silicon and oxygen or nitrogen.

The oxide semiconductor layer 41 is, for example, a columnar body extending in the Z-axis direction. The oxide semiconductor layer 41 passes the conductive layer 42 in the Z-axis direction. The oxide semiconductor layer 41 forms a channel of the memory transistor MTR. The oxide semiconductor layer 41 contains, for example, indium (In). The oxide semiconductor layer 41 contains, for example, an indium oxide and a gallium oxide, an indium oxide and a zinc oxide, or an indium oxide and a tin oxide. As an example, the oxide semiconductor layer 41 contains an oxide containing indium, gallium, and zinc (indium-gallium-zinc-oxide), so-called InGaZnO (IGZO).

One end of the oxide semiconductor layer 41 in the Z-axis direction is connected to the conductive layer 31 via the conductive oxide layer 32 and functions as the other of the source or the drain of the memory transistor MTR. The conductive oxide layer 32 is provided between the electrical conductor 23 of the memory capacitor MCP and the oxide semiconductor layer 41 of the memory transistor MTR, and functions as the other of the source electrode or the drain electrode of the memory transistor MTR.

The conductive layer 42 includes a portion facing the oxide semiconductor layer 41 with the insulating film 43 sandwiched in the X-Y plane. The conductive layer 42 forms a gate electrode of the memory transistor MTR and forms the word line WL as wiring. The conductive layer 42 contains, for example, a metal, a metal compound, or a semiconductor. The conductive layer 42 contains, for example, at least one material selected from the group consisting of tungsten (W), titanium (Ti), titanium nitride (TiN), molybdenum (Mo), cobalt (Co), and ruthenium (Ru).

The plurality of conductive layers 42 extend in the X-axis direction and are disposed in parallel to each other. Each of the conductive layers 42 overlaps and is connected to the plurality of memory cells MC in the X-axis direction.

The insulating film 43 is provided between the oxide semiconductor layer 41 and the conductive layer 42 in the X-Y plane. The insulating film 43 forms a gate insulating film of the memory transistor MTR. The insulating film 43 contains, for example, silicon, and oxygen or nitrogen. The insulating film 43 may be a stacked film of a plurality of insulating films.

The memory transistor MTR is a so-called surrounding gate transistor (SGT) in which a gate electrode surrounds a channel. The area of the semiconductor device can be reduced by SGT.

The field effect transistor including the channel layer containing the oxide semiconductor has a lower off-leakage current than that of the field effect transistor provided on the semiconductor substrate 10. Therefore, for example, since the data stored in the memory cell MC can be stored for a long time, the number of times of the refresh operation can be reduced. In addition, since the field effect transistor including the channel layer containing the oxide semiconductor can be formed by a low-temperature process, it is possible to reduce the application of thermal stress to the memory capacitor MCP.

The intermediate layer 51 is provided on the oxide semiconductor layer 41. The intermediate layer 51 contains a conductive oxide of the embodiment. As described above, the intermediate layer 51 includes the metal layer 51a, a first oxide layer 51b, and a second oxide layer 51c.

The conductive layer 52 is provided on the intermediate layer 51 and is electrically connected to the intermediate layer 51. The conductive layer 52 contains, for example, copper.

The intermediate layer 51 and the conductive layer 52 form the conductor 50. The conductor 50 is electrically connected to the sense amplifier via the bit line BL. The conductor 50 has a function as a conductive pad for connecting the memory transistor MTR and the bit line BL, for example. A plurality of the conductors 50 correspond to the plurality of memory transistors MTR. An insulating layer 53 is formed between the plurality of conductors 50. The insulating layer 53 contains, for example, silicon and oxygen or nitrogen.

The other end of the oxide semiconductor layer 41 in the Z-axis direction is connected to the conductive layer 52 via the intermediate layer 51 and functions as one of the source and the drain of the memory transistor MTR. The intermediate layer 51 functions as one of the source electrode and the drain electrode of the memory transistor MTR.

The conductive layer 71 is provided on the conductive layer 52 and is connected to the conductor 50. The conductive layer 71 forms the bit line BL as wiring. An insulating layer 72 is formed between a plurality of the conductive layers 71. The insulating layer 72 contains, for example, silicon and oxygen or nitrogen.

The plurality of memory cells MC may be arranged in a staggered manner in the X-Y plane. The memory cell MC connected to one of the plurality of word lines WL is shifted in the X-axis direction with respect to the memory cell MC connected to the adjacent word line WL. As a result, the integration degree of the memory cell MC can be increased.

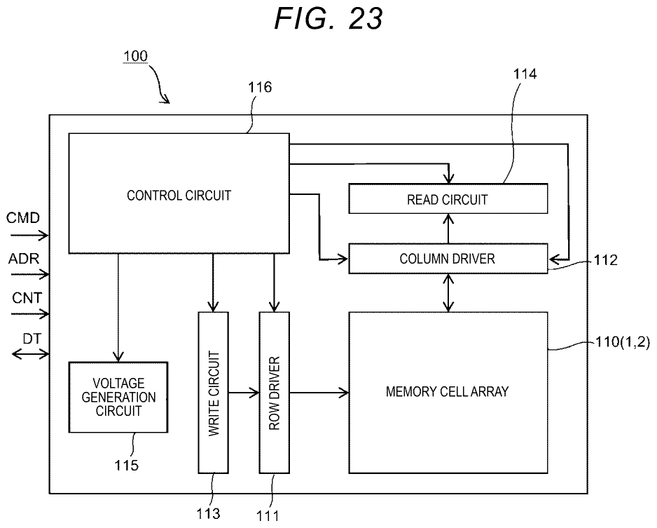

FIG. 23 is a block diagram showing a configuration example of the semiconductor memory device of the embodiment. A semiconductor memory device 100 includes a memory cell array 110, a row driver 111, a column driver 112, a write circuit 113, a read circuit 114, a voltage generation circuit 115, and a control circuit 116. The memory cell array 110 includes the memory cell array 2 described in FIG. 21 and FIG. 22, and the semiconductor device 1 according to the above-described embodiment.

The row driver 111 controls a plurality of rows of the memory cell array 110. The row driver 111 receives a low address signal from the control circuit 116 based on a decoding result of an address signal ADR input from the outside. The row driver 111 sets the word line WL of a row selected by the row address signal to be in a selected state. The row driver 111 includes, for example, a circuit such as a multiplexer (word line selection circuit) and a word line driver.

The column driver 112 controls a plurality of columns of the memory cell array 110. The column driver 112 receives a column address signal based on a decoding result of the address signal ADR from the control circuit 116. The column driver 112 sets the bit line BL of a column selected by the column address signal to be in a selected state. The column driver 112 includes, for example, a circuit such as a multiplexer (bit line selection circuit) or a bit line driver.

The write circuit 113 performs various types of control for a data write operation. The write circuit 113 receives a data signal DT input from the outside. The write circuit 113 supplies a write pulse formed by a current and(or) a voltage to the memory cell array 110 during a write operation. Thereby, the data can be written to the memory cell MC. The write circuit 113 is electrically connected to the memory cell array 110 via the row driver 111. The write circuit 113 includes, for example, a circuit such as a voltage source and(or) a current source, a pulse generation circuit, or a latch circuit.

The read circuit 114 performs various types of control for a data read operation. The read circuit 114 supplies a read pulse (for example, a read voltage) to the memory cell array 110 during a read operation. The read circuit 114 senses a potential or a current value of the bit line BL. Based on this sense result, data in the memory cell MC can be read. The read circuit 114 transfers the read data signal to the outside. The read circuit 114 is connected to the memory cell array 110 via the column driver 112. The read circuit 114 includes, for example, a circuit such as a voltage source and(or) a current source, a pulse generation circuit, a latch circuit, or a sense amplifier circuit.

The write circuit 113 and the read circuit 114 are not limited to circuits that are independent of each other. For example, the write circuit 113 and the read circuit 114 may include common elements that can be used together and may be disposed in the semiconductor memory device 100 as one integrated circuit.

The voltage generation circuit 115 generates a voltage for various operations of the memory cell array 110 by using a power supply voltage supplied from the outside. The voltage generation circuit 115 supplies the generated various voltages to each of the row driver 111, the column driver 112, the write circuit 113, and the read circuit 114.

The control circuit 116 includes, for example, a command register and an address register. The control circuit 116 controls the row driver 111, the column driver 112, the write circuit 113, the read circuit 114, and the voltage generation circuit 115 based on, for example, a command signal CMD, an address signal ADR, and a control signal CNT input from the outside, and executes an operation such as a read operation, a write operation, and an erase operation.

The command signal CMD is a signal indicating an operation to be executed by the semiconductor memory device 100. For example, the address signal ADR is a signal indicating coordinates of one or more memory cells MC (referred to as a selected cell) that are operation targets in the memory cell array 110. The address signal ADR includes a row address signal and a column address signal of the memory cell MC. The control signal CNT is, for example, a signal for controlling an operation timing between the semiconductor memory device 100 and an external device and an operation timing inside the semiconductor memory device 100.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a channel including an oxide semiconductor; and
an electrode in contact with the channel,
wherein the electrode includes:
a metal layer including at least one of the following metal elements: iridium, palladium, silver, osmium, and rhodium; and
a first oxide layer in contact with the metal layer, disposed between the metal layer and the channel, and including the metal element of the metal layer.

2. The semiconductor device according to claim 1,
wherein the electrode further includes a second oxide layer between the first oxide layer and the channel.

3. The semiconductor device according to claim 2,
wherein the second oxide layer includes indium and tin.

4. The semiconductor device according to claim 1,
wherein the oxide semiconductor includes at least one of: indium, gallium, zinc, or tin.

5. The semiconductor device according to claim 1,
wherein the electrode is configured as a source electrode and/or a drain electrode.

6. A semiconductor memory device, comprising:
a channel including an oxide semiconductor;
an electrode in contact with the channel; and
a capacitor electrically connected to the channel,
wherein the electrode includes:
a metal layer including at least one of the following metal elements: iridium, palladium, silver, osmium, and rhodium; and
a first oxide layer in contact with the metal layer, disposed between the metal layer and the channel, and including the metal element of the metal layer.

7. The semiconductor memory device according to claim 6,
wherein the electrode includes a second oxide layer between the first oxide layer and the channel.

8. The semiconductor memory device according to claim 7,
wherein the second oxide layer includes indium and tin.

9. The semiconductor memory device according to claim 6,
wherein the oxide semiconductor includes at least one of: indium, gallium, zinc, or tin.

10. The semiconductor memory device according to claim 6, wherein the electrode is configured as a source electrode and/or a drain electrode.

11. The semiconductor memory device according to claim 6,
wherein the capacitor is electrically connected to the channel via the electrode.

12. A semiconductor device, comprising:
a channel including an oxide semiconductor; and
an electrode in contact with the channel,
wherein the electrode includes:
a metal layer including at least one of the following metal elements: iridium, palladium, silver, osmium, and rhodium; and
a first oxide layer in contact with the metal layer, disposed between the metal layer and the channel, and including the metal element of the metal layer, and
wherein the channel is disposed above a substrate and extends in a vertical direction to a surface of the substrate, with the electrode disposed above the channel.

13. The semiconductor device according to claim 12, wherein the first oxide layer is separated from the channel with a second oxide layer.

14. The semiconductor device according to claim 13, wherein the first oxide layer includes at least one of: iridium oxide (IrOx), palladium oxide (PdOx), silver oxide (AgOx), osmium oxide (OsOx), or a rhodium oxide (RhOx).

15. The semiconductor device according to claim 14, wherein the second oxide layer includes indium tin oxide (ITO).
